(19) United States
(12) Patent Application Publication
(10) Pub. No.: US 2020/0303948 A1
(43) Pub. Date: Sep. 24, 2020

(54) CIRCUIT SYSTEM WITH PLURAL POWER DOMAINS

(71) Applicant: FARADAY TECHNOLOGY CORPORATION, Hsinchu (TW)

(72) Inventor: Chun-Yuan LAI, Hsinchu (TW)

(21) Appl. No.: 16/459,680

(22) Filed: Jul. 2, 2019

(30) Foreign Application Priority Data
Mar. 18, 2019 (TW) 108109141

(51) Int. Cl. H02J 9/06

(52) U.S. Cl. CPC H02J 9/061; H03K 19/20

(57) ABSTRACT

A circuit system includes a first power source, a second power source, a first interface circuit, a second interface circuit and an isolation circuit. The first interface circuit is included in a first power domain. The second interface circuit is includes in a second power domain. The bus signal group from the first interface circuit is transmitted to the second interface circuit through the isolation circuit. In a power-saving mode, the bus signal group in a floating state can be effectively isolated by the isolation circuit. If a sudden power interruption event occurs when the circuit system is in the normal working mode, the bus signal group in the floating state is isolated by the isolation circuit. Moreover, the isolation circuit is capable of filtering off the incomplete transaction data, and thus the second interface circuit is not suffered from malfunction.

This application claims the benefit of Taiwan Patent Application No. 108109141, filed Mar. 18, 2019, the subject matter of which is incorporated herein by reference.

### FIELD OF THE INVENTION

The present invention relates to a circuit system, and more particularly to a circuit system with plural power domains.

### BACKGROUND OF THE INVENTION

Generally, a circuit system is equipped with plural power domains in order to reduce the power loss. For example, the circuit system is an integrated circuit. When the circuitry components in a specified power domain are not in the usage state, the circuit system stops providing electric power to the specified power domain. Consequently, the power-saving efficacy is achieved. Moreover, the circuit system further comprises an isolation circuit between the power domains in order to allow for the normal operation of the circuit system.

FIG. 1 is a schematic diagram illustrating a conventional circuit system with plural power domains. As shown in FIG. 1, the circuit system 100 comprises a first power source 130, a second power source 140, a first interface circuit 115, a power switch circuit 132, a logical AND gate group 122, a second interface circuit 124 and a power control circuit 126. Moreover, an isolation circuit is defined by the power control circuit 126, the power switch circuit 132 and the logical AND gate group 122 collaboratively.

The first interface circuit 115 is included in a first power domain 110. The logical AND gate group 122, the second interface circuit 124 and the power control circuit 126 are included in a second power domain 120. The first interface circuit 115 in the first power domain 110 is powered by a first voltage V1 from the first power source 130. The logical AND gate group 122, the second interface circuit 124 and the power control circuit 126 in the second power domain 120 are powered by a second voltage V2 from the second power source 140. The power control circuit 126 controls the power switch circuit 132 to selectively provide the first voltage V1 to the first power domain 110.

According to the design of the conventional circuit system, the first power domain 110 is an OFF domain and the second power domain 120 is an ON power domain. That is, when the circuit system 100 is in a power-saving mode, the first voltage V1 is not supplied to the OFF domain (i.e., the first power domain 110). Consequently, all circuits in the OFF domain (i.e., the first power domain 110) are disabled. In any mode of the circuit system 100, the second voltage V2 is continuously supplied to the ON power domain (i.e., the second power domain 120). Consequently, all circuits in the ON power domain (i.e., the second power domain 120) can be normally operated.

Please refer to the circuit system 100 of FIG. 1 again. When the circuit system 100 is in a normal working mode, an isolation signal ISO in a logical high level state is outputted from the power control circuit 126. In addition, the power switch circuit 132 is enabled according to a power enabling signal PWR_en from the power control circuit 126. Consequently, the first voltage V1 from the first power source 130 is transmitted to the first power domain 110 through the power switch circuit 132. Consequently, the first interface circuit 115 is normally operated to output a bus signal group Bus[1:n].

A first terminal of the logical AND gate group 122 receives the isolation signal ISO in the logical high level state. A second terminal of the logical AND gate group 122 receives the bus signal group Bus[1:n]. Consequently, the output terminal of the logical AND gate group 122 issues the bus signal group Bus[1:n] to the second interface circuit 124.

When the circuit system 100 is in a power-saving mode, the isolation signal ISO in a logical low level state is outputted from the power control circuit 126 to the first terminal of the logical AND gate group 122. Consequently, the bus signal group Bus[1:n] is isolated by the logical AND gate group 122. Meanwhile, regardless of whether the bus signal group Bus[1:n] is in the logical high level state or the logical low level state, the output terminal of the logical AND gate group 122 issues the logical low level signal to the second interface circuit 124.

Then, the power switch circuit 132 is disabled according to the power enabling signal PWR_en from the power control circuit 126. Consequently, the first voltage V1 is not supplied to the first power domain 110 through the power switch circuit 132. Since the first interface circuit 115 is disabled, the bus signal group Bus[1:n] is in a floating state. Meanwhile, the bus signal group Bus[1:n] in the floating state is isolated by the logical AND gate group 122.

The logical AND gate group 122 comprises n AND gates. For example, n is equal to 8. That is, the logical AND gate group 122 comprises 8 AND gates. The first terminals of the 8 AND gates receive the corresponding signals of the 8 signals in the bus signal group Bus[1:8]. The second terminals of the 8 AND gates receive the isolation signal ISO. When the isolation signal ISO in a logical high level state is received by the logical AND gate group 122, the bus signal group Bus[1:n] is outputted from the output terminal of the logical AND gate group 122. In contrast, when the isolation signal ISO in the logical low level state is received by the logical AND gate group 122, the bus signal group Bus[1:n] is isolated by the output terminal of the logical AND gate group 122. In addition, the output terminal of the logical AND gate group 122 issues the logical low level signal.

As mentioned above, the conventional circuit system 100 uses the isolation circuit to selectively isolate the bus signal group Bus[1:n]. However, in some situations, the conventional circuit system 100 still has some drawbacks. For example, in case that the first power source 130 is a battery and the second power source 140 is a main power source, the circuit system 100 is possibly suffered from malfunction or the circuit system 100 generates extra power loss. The reasons will be described as follows.

In the normal working mode, the main power source (i.e., the second power source 140) provides the second voltage V2 to the second power domain 120. Meanwhile, the isolation signal ISO in the logical high level state is outputted from the power control circuit 126. In addition, the power switch circuit 132 is enabled according to the power enabling signal PWR_en from the power control circuit 126.

If the residual capacity of the battery (i.e., the first power source 130) is insufficient to provide the first voltage V1 and the power interruption event occurs, the first interface circuit 115 of the first power domain 110 is disabled. Consequently, the bus signal group Bus[1:n] is in the floating state.

Since the isolation signal ISO from the power control circuit 126 is in the logical high level state when the circuit system 100 is in the normal working mode, the bus signal group Bus[1:n] in the floating state cannot be isolated by the logical AND gate group 122. Subsequently, the circuitry of the second power domain 120 receives the bus signal group Bus[1:n]. Under this circumstance, the transistors in the circuitry of the second power domain 120 are in a semi-conducting state to generate leakage current. The leakage current results in the extra power loss or even results in the malfunction of the circuit system 100.

### SUMMARY OF THE INVENTION

An embodiment of the present invention provides a circuit system with plural power domains. The steps of includes a first power source, a second power source, a first interface circuit, a transaction monitoring circuit, a voltage detector, a logical gate, a logical circuit and a second interface circuit. The first power source provides a first voltage to a first power domain. The second power source provides a second voltage to a second power domain. The first interface circuit is included in the first power domain. When the first interface circuit is enabled, the first interface circuit issues a bus signal group. The transaction monitoring circuit is included in the first power domain and connected with the first interface circuit. When the transaction monitoring circuit is enabled, the transaction monitoring circuit judges the bus signal group. If a transaction process is being performed on the bus signal group, the transaction monitoring circuit activates a transaction judgment signal. If the transaction process is not being performed on the bus signal group, the transaction monitoring circuit inactivates the transaction judgment signal. The voltage detector is included in the second power domain and connected with the first power source. If the first voltage supplied from the first power source is received by the voltage detector, the voltage detector activates a power confirmation signal. If the first voltage is not supplied from the first power source, the voltage detector inactivates the power confirmation signal. The logical gate is included in the second power domain to receive the transaction judgment signal and the power confirmation signal. If one of the transaction judgment signal and the power confirmation signal is inactivated, the logical gate activates an isolation signal. If both of the transaction judgment signal and the power confirmation signal are activated, the logical gate inactivates the isolation signal. The logical circuit is included in the second power domain, and receiving the isolation signal and the bus signal group. If the isolation signal is inactivated, the bus signal group is outputted from an output terminal of the logical circuit. If the isolation signal is activated, the bus signal group is isolated by the logical circuit. The second interface circuit is included in the second power domain, and receives a transaction data corresponding to the transaction process.

Numerous objects, features and advantages of the present invention will be readily apparent upon a reading of the following detailed description of embodiments of the present invention when taken in conjunction with the accompanying drawings. However, the drawings employed herein are for the purpose of descriptions and should not be regarded as limiting.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 (prior art) is a schematic diagram illustrating a conventional circuit system with plural power domains;

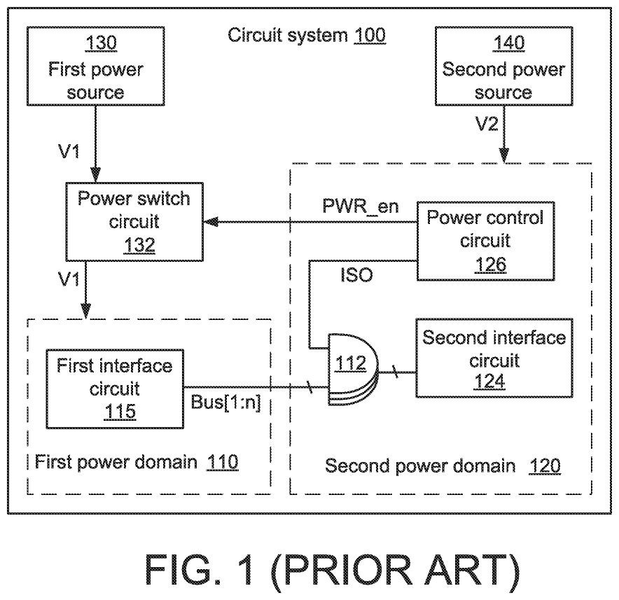

FIG. 2 is a schematic diagram illustrates the architecture of a circuit system with plural power domains according to a first embodiment of the present invention; and

FIG. 3 is a schematic diagram illustrates the architecture of a circuit system with plural power domains according to a second embodiment of the present invention.

### DETAILED DESCRIPTION OF PREFERRED EMBODIMENTS

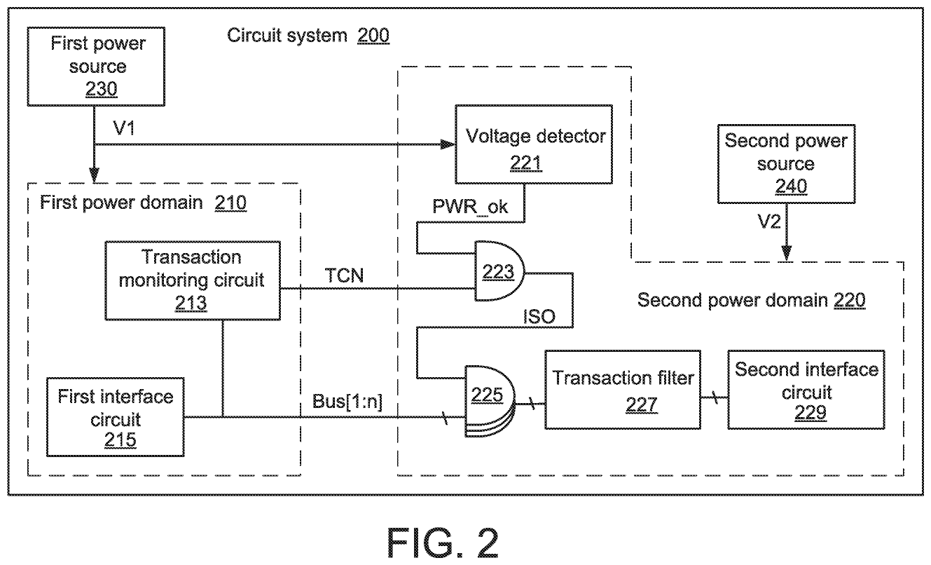

FIG. 2 is a schematic diagram illustrates the architecture of a circuit system with plural power domains according to a first embodiment of the present invention. As shown in FIG. 2, the circuit system 200 comprises a first power source 230, a second power source 240, a transaction monitoring circuit 213, a first interface circuit 215, a voltage detector 221, an AND gate 223, a logical AND gate group 225, a transaction filter 227 and a second interface circuit 229. Moreover, an isolation circuit is defined by the transaction monitoring circuit 213, the voltage detector 221, the AND gate 223, the logical AND gate group 225 and the transaction filter 227 collaboratively.

The first interface circuit 215 and the transaction monitoring circuit 213 are included in a first power domain 210. The voltage detector 221, the AND gate 223, the logical AND gate group 225, the transaction filter 227 and the second interface circuit 229 are included in a second power domain 220. The transaction monitoring circuit 213 and the first interface circuit 215 in the first power domain 210 are powered by a first voltage V1 from the first power source 230. The voltage detector 221, the AND gate 223, the logical AND gate group 225, the transaction filter 227 and the second interface circuit 229 in the second power domain 220 are powered by a second voltage V2 from the second power source 240.

The first power domain 210 is an OFF domain, and the second power domain 220 is an ON power domain. That is, when the circuit system 200 is in a power-saving mode, the first voltage V1 is not supplied from the first power source 230 to the OFF domain (i.e., the first power domain 210). Consequently, all circuits in the OFF domain (i.e., the first power domain 210) are disabled. In any mode of the circuit system 200, the second voltage V2 is continuously supplied from the second power source 240 to the ON power domain (i.e., the second power domain 220). Consequently, all circuits in the ON power domain (i.e., the second power domain 220) can be normally operated.

For example, when the circuit system 200 is in a normal working mode, the first power source 230 provides the first voltage V1 to the first power domain 210. Consequently, the first interface circuit 215 and the transaction monitoring circuit 213 can be normally operated. At the same time, the second power source 240 provides the second voltage V2 to the second power domain 220. Consequently, the voltage detector 221, the AND gate 223, the logical AND gate group 225, the transaction filter 227 and the second interface circuit 229 can be normally operated.

In the first power domain 210, the transaction monitoring circuit 213 is electrically connected with the first interface circuit 215. The transaction monitoring circuit 213 is used for judging whether the transaction process corresponding to the bus signal group Bus[1:n] is being performed. According to the judging result, the transaction monitoring circuit 213 generates a transaction judgment signal TCN. If the transaction process corresponding to the bus signal group Bus[1:n] is being performed, the transaction judgment signal TCN is activated by the transaction monitoring circuit 213. Meanwhile, the transaction judgment signal TCN is in a logical high level state. Whereas, if the transaction process corresponding to the bus signal group Bus[1:n] is not being performed, the transaction judgment signal TCN is inactivated by the transaction monitoring circuit 213. Meanwhile, the transaction judgment signal TCN is in a logical low level state.

For example, when a transaction process of the first interface circuit 215 is performed, a transaction data comprising an operation command and an address data is generated. The transaction data is transmitted to the second interface circuit 229 through the bus signal group Bus[1:n]. If the transaction monitoring circuit 213 judges that the transaction between the first interface circuit 215 and the second interface circuit 229 is being performed according to the content of the bus signal group Bus[1:n], the transaction monitoring circuit 213 activates the transaction judgment signal TCN. Meanwhile, the transaction judgment signal TCN is in the logical high level state. Whereas, if the transaction monitoring circuit 213 judges that the signals in the bus signal group Bus[1:n] are unchanged or contain noise, the transaction monitoring circuit 213 inactivates the transaction judgment signal TCN. Meanwhile, the transaction judgment signal TCN is in the logical low level state.

In another embodiment, a valid signal is contained in the bus signal group Bus[1:n]. If the transaction process is being performed by the first interface circuit 215, the valid signal is activated. If the transaction process is not being performed by the first interface circuit 215, the valid signal is inactivated. According to the valid signal, the transaction monitoring circuit 213 can judge whether the transaction between the first interface circuit 215 and the second interface circuit 229 is being performed. If the valid signal is activated, the transaction monitoring circuit 213 activates the transaction judgment signal TCN and thus the transaction judgment signal TCN is in the logical high level state. Whereas, if the valid signal is inactivated, the transaction monitoring circuit 213 inactivates the transaction judgment signal TCN and thus the transaction judgment signal TCN is in the logical low level state.

The voltage detector 221 of the second power domain 220 is connected with the first power source 230. When the first voltage V1 supplied from the first power source 230 is received by the voltage detector 221, the voltage detector 221 generates and activates a power confirmation signal PWR_ok. Meanwhile, the power confirmation signal PWR_ok is in the logical high level state. Whereas, if the first voltage V1 is not supplied from the first power source 230, the voltage detector 221 inactivates the power confirmation signal PWR_ok. Meanwhile, the power confirmation signal PWR_ok is in the logical low level state.

The AND gate 223 is connected with the transaction monitoring circuit 213 and the voltage detector 221. The AND gate 223 receives the transaction judgment signal TCN and the power confirmation signal PWR_ok and generates an isolation signal ISO. If one of the transaction monitoring circuit 213 and the voltage detector 221 is disabled, the isolation signal ISO is activated by the AND gate 223. Meanwhile, the isolation signal ISO is in the logical low level state. If both of the transaction monitoring circuit 213 and the voltage detector 221 are disabled, the isolation signal ISO is not activated. Meanwhile, the isolation signal ISO is in the logical high level state.

The logical AND gate group 225 comprises n AND gates. For example, n is equal to 8. That is, the logical AND gate group 225 comprises 8 AND gates. The first terminals of the 8 AND gates receive the corresponding signals of the 8 signals in the bus signal group Bus[1:8]. The second terminals of the 8 AND gates receive the isolation signal ISO. The output terminals of the 8 AND gates are connected with the transaction filter 227. When the isolation signal ISO is inactivated (i.e., in the logical high level state), the bus signal group Bus[1:n] is outputted from the output terminal of the logical AND gate group 225 to the transaction filter 227. In contrast, when the isolation signal ISO is activated (i.e., in the logical low level state), the bus signal group Bus[1:n] is isolated by the logical AND gate group 225. In addition, the output terminal of the logical AND gate group 225 issues the logical low level signal to the transaction filter 227.

The transaction filter 227 is connected between the output terminal of the logical AND gate group 225 and the second interface circuit 229. The transaction filter 227 judges whether the content of the bus signal group Bus[1:n] from the logical AND gate group 225 contains a complete transaction data. If the transaction filter 227 judges that the content of the bus signal group Bus[1:n] contains the complete transaction data, the complete transaction data is transmitted to the second interface circuit 229. Whereas, if the transaction filter 227 judges that the content of the bus signal group Bus[1:n] contains an incomplete transaction data or does not contain any transaction data, the transaction data is discarded and not transmitted to the second interface circuit 229.

In another embodiment, the circuit system is not equipped with the transaction filter 227. That is, the second interface circuit 229 is connected with the output terminal of the logical AND gate group 225 directly. After the incomplete transaction data is transmitted to the second interface circuit 229, the incomplete transaction data is processed by the second interface circuit 229. Although it takes more time for the second interface circuit 229 to process the incomplete transaction data, the purpose of the present invention is achievable.

The operations of the circuit system 200 in a normal working mode and in a power-saving mode and the operations of the circuit system 200 when a sudden power interruption event occurs in the normal working mode will be described as follows.

When the circuit system 200 in the normal working mode, the voltage detector 221 activates the power confirmation signal PWR_ok. Meanwhile, the power confirmation signal PWR_ok is in the logical high level state. If the transaction process is being performed by the first interface circuit 215, the transaction judgment signal TCN is activated by the transaction monitoring circuit 213. Meanwhile, the transaction judgment signal TCN is in the logical high level state. Since the isolation signal ISO is inactivated (i.e., in the logical high level state) by the AND gate 223, the bus signal group Bus[1:n] is transmitted from the first interface circuit 215 to the second interface circuit 229 through the logical AND gate group 225 and the transaction filter 227.

When the circuit system 200 in the normal working mode, the voltage detector 221 activates the power confirmation signal PWR_ok. Meanwhile, the power confirmation signal PWR_ok is in the logical high level state. If the transaction process is not being performed by the first interface circuit 215, the transaction judgment signal TCN is inactivated by the transaction monitoring circuit 213. Meanwhile, the transaction judgment signal TCN is in the logical low level state. Consequently, the isolation signal ISO is activated by the AND gate 223. Meanwhile, the isolation signal ISO is in the logical low level state. Since the transaction process is not being performed by the first interface circuit 215, the second interface circuit 229 does not need to receive the bus signal group Bus[1:n]. Under this circumstance, the bus signal group Bus[1:n] is directly isolated by the logical AND gate group 225. Consequently, the bus signal group Bus[1:n] is not transmitted to the second interface circuit 229.

When the circuit system 200 is in a power-saving mode, the first voltage V1 is not supplied from the first power source 230 to the first power domain 210. Meanwhile, the transaction monitoring circuit 213 and the first interface circuit 215 are disabled. Consequently, the transaction judgment signal TCN and the bus signal group Bus[1:n] are in a floating state. Moreover, the voltage detector 221 of the second power domain 220 inactivates the power confirmation signal PWR_ok. Meanwhile, the power confirmation signal PWR_ok is in the logical low level state. Consequently, the isolation signal ISO is activated by the AND gate 223. Meanwhile, the isolation signal ISO is in the logical low level state. Since the first interface circuit 215 is disabled, the bus signal group Bus[1:n] in the floating state is isolated by the logical AND gate group 225 according to the activated isolation signal ISO. Consequently, the bus signal group Bus[1:n] is not transmitted to the second interface circuit 229.

When the circuit system 200 in the normal working mode and the transaction process is being performed by the first interface circuit 215, the bus signal group Bus[1:n] can be transmitted from the first interface circuit 215 to the second interface circuit 229. However, if the first power source 230 is unable to supply the first voltage V1 to the first power domain 210, a power interruption of the first power source 230 occurs. Consequently, the power confirmation signal PWR_ok is inactivated by the voltage detector 221 immediately, and the isolation signal ISO is activated by the AND gate 223 immediately. Meanwhile, the power confirmation signal PWR_ok is in the logical low level state, and the isolation signal ISO is in the logical low level state. According to the activated isolation signal ISO, the bus signal group Bus[1:n] in the floating state is isolated by the logical AND gate group 225.

In some situations, a sudden power interruption event of the first power source 230 occurs when the transaction process is being performed by the first interface circuit 215. Meanwhile, the transaction process is not completed. By the transaction filter 227, the incomplete transaction data corresponding to the transaction process is not transmitted to the second interface circuit 229.

Generally, whenever a transaction process of the first interface circuit 215 is performed, a transaction data comprising an operation command and an address data is generated. The transaction data is transmitted to the second interface circuit 229 through the bus signal group Bus[1:n].

If the sudden power interruption event of the first power source 230 occurs when the transaction process of the first interface circuit 215 generates the operation command but has not generated the address data, the transaction filter 227 will filter off the incomplete transaction data. Since the incomplete transaction data is not transmitted to the second interface circuit 229, the second interface circuit 229 is not suffered from malfunction.

It is noted that numerous modifications and alterations may be made while retaining the teachings of the invention. For example, the AND gate 223 and the logical AND gate group 225 may be replaced by other logical gate and other logical circuit.

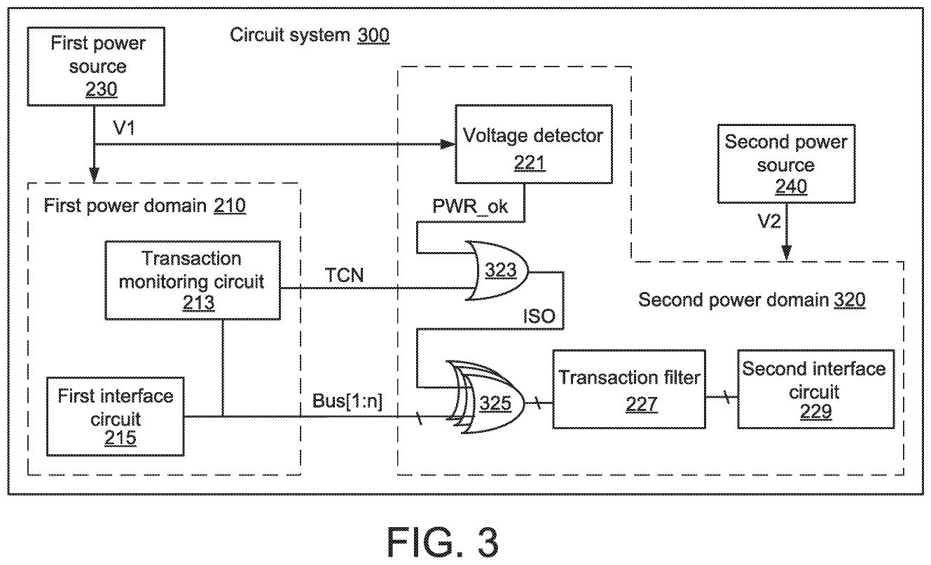

FIG. 3 is a schematic diagram illustrates the architecture of a circuit system with plural power domains according to a second embodiment of the present invention. In comparison with the first embodiment, the second power domain 320 of the circuit system 300 of this embodiment is distinguished. For example, the AND gate 223 and the logical AND gate group 225 are replaced by an OR gate 323 and a logical OR gates 325, respectively.

In this embodiment, the OR gate 323 receives the transaction judgment signal TCN and the power confirmation signal PWR_ok and generates the isolation signal ISO. Moreover, the logical OR gates 325 receives the isolation signal ISO and the bus signal group Bus[1:n]. The connecting relationships between other components are similar to those of the first embodiment, and are not redundantly described herein.

If the transaction process corresponding to the bus signal group Bus[1:n] is being performed, the transaction judgment signal TCN is activated by the transaction monitoring circuit 213. Meanwhile, the transaction judgment signal TCN is in the logical low level state. Whereas, if the transaction process corresponding to the bus signal group Bus[1:n] is not being performed, the transaction judgment signal TCN is inactivated by the transaction monitoring circuit 213. Meanwhile, the transaction judgment signal TCN is in the logical high level state. When the first voltage V1 supplied from the first power source 230 is received by the voltage detector 221, the voltage detector 221 activates a power confirmation signal PWR_ok. Meanwhile, the power confirmation signal PWR_ok is in the logical low level state. Whereas, if the first voltage V1 is not supplied from the first power source 230, the voltage detector 221 inactivates the power confirmation signal PWR_ok. Meanwhile, the power confirmation signal PWR_ok is in the logical high level state.

When the circuit system 300 in the normal working mode, the voltage detector 221 activates the power confirmation signal PWR_ok. Meanwhile, the power confirmation signal PWR_ok is in the logical low level state. If the transaction process is being performed by the first interface circuit 215, the transaction judgment signal TCN is activated by the transaction monitoring circuit 213. Meanwhile, the transaction judgment signal TCN is in the logical low level state. Since the isolation signal ISO is inactivated (i.e., in the logical low level state) by the OR gate 323, the bus signal group Bus[1:n] is transmitted from the first interface circuit 215 to the second interface circuit 229 through the logical OR gates 325 and the transaction filter 227.

When the circuit system 300 in the normal working mode, the voltage detector 221 activates the power confirmation signal PWR_ok. Meanwhile, the power confirmation signal PWR_ok is in the logical low level state. If the transaction process is not being performed by the first interface circuit 215, the transaction judgment signal TCN is inactivated by the transaction monitoring circuit 213. Meanwhile, the transaction judgment signal TCN is in the logical high level state. Consequently, the isolation signal ISO is activated by the OR gate 323. Meanwhile, the isolation signal ISO is in the logical high level state. Since the transaction process is not being performed by the first interface circuit 215, the second interface circuit 229 does not need to receive the bus signal group Bus[1:n]. Under this circumstance, the bus signal group Bus[1:n] is directly isolated by the logical OR gates 325 according to the activated isolation signal ISO (i.e., in the logical high level state). Consequently, the bus signal group Bus[1:n] is not transmitted to the second interface circuit 229.

When the circuit system 300 is in a power-saving mode, the first voltage V1 is not supplied from the first power source 230 to the first power domain 210. Meanwhile, the transaction monitoring circuit 213 and the first interface circuit 215 are disabled. Consequently, the transaction judgment signal TCN and the bus signal group Bus[1:n] are in a floating state. Moreover, the voltage detector 221 of the second power domain 320 inactivates the power confirmation signal PWR_ok. Meanwhile, the power confirmation signal PWR_ok is in the logical high level state. Consequently, the isolation signal ISO is activated by the OR gate 323. Meanwhile, the isolation signal ISO is in the logical high level state. Since the first interface circuit 215 is disabled, the bus signal group Bus[1:n] in the floating state is isolated by the logical OR gates 325 according to the activated isolation signal ISO. Consequently, the bus signal group Bus[1:n] is not transmitted to the second interface circuit 229.

When the circuit system 300 in the normal working mode and the transaction process is being performed by the first interface circuit 215, the bus signal group Bus[1:n] can be transmitted from the first interface circuit 215 to the second interface circuit 229. However, if first power source 230 is unable to supply the first voltage V1 to the first power domain 210, a power interruption of the first power source 230 occurs. Consequently, the power confirmation signal PWR_ok is inactivated by the voltage detector 221 immediately, and the isolation signal ISO is activated by the OR gate 323 immediately. Meanwhile, the power confirmation signal PWR_ok is in the logical high level state, and the isolation signal ISO is in the logical high level state. According to the activated isolation signal ISO, the bus signal group Bus[1:n] in the floating state is isolated by the logical AND gate group 225. By the transaction filter 227, the incomplete transaction data corresponding to the transaction process is not transmitted to the second interface circuit 229.

In some other embodiments, the AND gate or the OR gate is replaced by other logical circuit.

From the above descriptions, the present invention provides a circuit system with plural power domains. When the circuit system is in the power-saving mode, the bus signal group Bus[1:n] in a floating state can be effectively isolated by the isolation circuit of the circuit system. If a sudden power interruption event occurs when the circuit system is in the normal working mode, the bus signal group Bus[1:n] in the floating state is isolated by the isolation circuit and the circuitry in the second power domain is not adversely affected. Moreover, the isolation circuit is capable of filtering off the incomplete transaction data, and thus the second interface circuit is not suffered from malfunction.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A circuit system with plural power domains, the circuit system comprising:
a first power source providing a first voltage to a first power domain;
a second power source providing a second voltage to a second power domain;
a first interface circuit included in the first power domain, wherein when the first interface circuit is enabled, the first interface circuit issues a bus signal group;
a transaction monitoring circuit included in the first power domain and connected with the first interface circuit, wherein when the transaction monitoring circuit is enabled, the transaction monitoring circuit judges the bus signal group, wherein if a transaction process is being performed on the bus signal group, the transaction monitoring circuit activates a transaction judgment signal, wherein if the transaction process is not being performed on the bus signal group, the transaction monitoring circuit inactivates the transaction judgment signal;
a voltage detector included in the second power domain and connected with the first power source, wherein if the first voltage supplied from the first power source is received by the voltage detector, the voltage detector activates a power confirmation signal, wherein if the first voltage is not supplied from the first power source, the voltage detector inactivates the power confirmation signal;
a logical gate included in the second power domain to receive the transaction judgment signal and the power confirmation signal, wherein if one of the transaction judgment signal and the power confirmation signal is inactivated, the logical gate activates an isolation signal, wherein if both of the transaction judgment signal and the power confirmation signal are activated, the logical gate inactivates the isolation signal;
a logical circuit included in the second power domain, and receiving the isolation signal and the bus signal group, wherein if the isolation signal is inactivated, the bus signal group is outputted from an output terminal of the logical circuit, wherein if the isolation signal is activated, the bus signal group is isolated by the logical circuit; and
a second interface circuit included in the second power domain, and receiving a transaction data corresponding to the transaction process.

2. The circuit system as claimed in claim 1, wherein the first power domain is an OFF domain, and the second power domain is an ON power domain.

3. The circuit system as claimed in claim 2, wherein the first power source is a battery, and the second power source is a main power source.

4. The circuit system as claimed in claim 1, wherein the bus signal group contains a valid signal, wherein if the valid signal is activated, the transaction monitoring circuit activates the transaction judgment signal, wherein if the valid signal is inactivated, the transaction monitoring circuit inactivates the transaction judgment signal.

5. The circuit system as claimed in claim 1, wherein the circuit system further comprises a transaction filter, which is included in the second power domain and arranged between the output terminal of the logical circuit and the second interface circuit, wherein if the transaction data corresponding to the transaction process of the bus signal group is complete, the transaction data is transmitted to the second interface circuit through the transaction filter, wherein if the transaction data corresponding to the transaction process of the bus signal group is incomplete, the transaction data is filtered off by the transaction filter.

6. The circuit system as claimed in claim 1, wherein the logical gate is an AND gate, the activated transaction judgment signal is in a logical high level state, the inactivated transaction judgment signal is in a logical low level state, the activated power confirmation signal is in the logical high level state, the inactivated power confirmation signal is in the logical low level state, the activated isolation signal is in the logical low level state, and the inactivated isolation signal is in the logical high level state.

7. The circuit system as claimed in claim 6, wherein the logical circuit is a logical AND gate group comprising plural AND gates, wherein first terminals of the plural AND gates receive corresponding signals of the bus signal group, second terminals of the plural AND gates receive the isolation signal, and output terminals of the plural AND gates are connected with the transaction filter.

8. The circuit system as claimed in claim 1, wherein the logical gate is an OR gate, the activated transaction judgment signal is in a logical low level state, the inactivated transaction judgment signal is in a logical high level state, the activated power confirmation signal is in the logical low level state, the inactivated power confirmation signal is in the logical high level state, the activated isolation signal is in the logical high level state, and the inactivated isolation signal is in the logical low level state.

9. The circuit system as claimed in claim 8, wherein the logical circuit is a logical OR gate group comprising plural OR gates, wherein first terminals of the plural OR gates receive corresponding signals of the bus signal group, second terminals of the plural OR gates receive the isolation signal, and output terminals of the plural OR gates are connected with the transaction filter.
